(19) United States
(12) Patent Application Publication
(10) Pub. No.: US 2021/0343972 A1
(43) Pub. Date: Nov. 4, 2021

(54) ACTIVE MATRIX ORGANIC LIGHT EMITTING DIODE (AMOLED) DISPLAY PANEL

(71) Applicant: WUHAN CHINA STAR OPTOELECTRONICS SEMICONDUCTOR DISPLAY TECHNOLOGY CO., LTD., Wuhan (CN)

(72) Inventors: Yuan Zheng, Wuhan (CN); Chihcheng Yen, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 16/467,735

(22) PCT Filed: Sep. 21, 2018
(86) PCT No.: PCT/CN2018/107010

§ 371 Date: Jun. 7, 2019

(30) Foreign Application Priority Data
Sep. 4, 2018 (CN) 201811022187.X

(51) Int. Cl. H01L 51/52; H01L 27/32; G06K 9/00; G06F 3/041; G06F 3/044

(52) U.S. Cl. CPC H01L 51/5215; H01L 51/5225; H01L 27/3246; G06F 2203/04111; G06K 9/0002; G06F 3/0412; G06F 3/0446; H01L 27/323

(57) ABSTRACT

The present disclosure provides an active matrix organic light emitting diode (AMOLED) display panel. The AMOLED display panel includes a base substrate and an anode layer, a pixel defining layer, a light emitting layer, a second metal layer, and a cathode layer formed on the base substrate. The cathode layer includes a plurality of cathodes and a plurality of sensing electrodes electrically insulated from the cathodes. A plurality of first electrode rows and a plurality of second electrode rows are formed by the sensing electrodes and insulated from each other. The sensing electrodes of the first electrode rows are used to couple to the sensing electrodes of the second electrode rows to make capacitors.

### CROSS REFERENCE TO RELATED APPLICATION

This application claims the priority of International Application No. PCT/CN2018/107010, filed on Sep. 21, 2018, which claims priority to Chinese Application No. 201811022187.X, filed on Sep. 4, 2018. The entire disclosures of each of the above applications are incorporated herein by reference.

### BACKGROUND OF INVENTION

### Field of Invention

The present invention relates to a display technology field, and particularly to an active-matrix organic light emitting diode (AMOLED) display panel.

### Description of Prior Art

Active-matrix organic light emitting diodes, referred to as AMOLEDs, or active matrix organic light emitting diode panels. At present, there are two types of fingerprint identification schemes on the market. One is a front fingerprint recognition integrated in a home button, and the other one is a rear fingerprint identification of the individual fingerprint recognition area on a back of the case. Both types of fingerprint recognition have certain deficiencies, the front-fingerprint affects proportion of the screen, and the back-fingerprint is not convenient.

FIG. 1 shows a design of a common fingerprint recognition, where the front fingerprint recognition is integrated in the home button, the fingerprint recognition unit and the display area are independent with each other, the fingerprint recognition is placed in a lower area of the display screen, which limits the screen ratio. A display screen area is labeled as 1; a effective light-emitting area is labeled as 2; and a single pixel area is labeled 3; Metal 1 is labeled as 4, connected to a first electrode of the light emitting diode, and formed as a whole, the entire effective light-emitting area shares a voltage; Metal 3 is labeled as 5, connected to a second electrode of the light-emitting diode, and each pixel corresponds to one Metal 3, provides different voltages for the diode; the fingerprint identification area is labeled as 6 and is integrated in the home button. In the pursuit of screen-to-body ratio or even full screen on smart phone, how to increase a screen-to-body ratio has become a hot spot.

Therefore, it is necessary to provide an AMOLED display panel to solve the problems existing in the prior art.

### SUMMARY OF THE INVENTION

The application mainly provides an AMOLED display panel to embed sensing electrodes into the AMOLED display panel and to achieve an underscreen fingerprint identification function, and to increase a ration of a display area to achieve full screen design.

For the above-mentioned objective, the present disclosure employs the following technical schemes.

The present disclosure provides an AMOLED display panel, the AMOLED display panel includes: a base substrate; an anode layer formed on the base substrate; a pixel defining layer formed on the anode layer, and defining a pixel region; a light emitting layer formed on the anode layer corresponding to the pixel region; a second metal layer formed on the pixel defining layer; and a cathode layer formed on the pixel defining layer and the second metal layer; the cathode layer includes a plurality of cathodes corresponding to the light emitting layer and a plurality of sensing electrodes electrically insulated from the cathodes, and a plurality of first electrode rows and a plurality of second electrode rows are formed by the sensing electrodes and insulated from each other.

In the AMOLED display panel of one embodiment of the present disclosure, the anode layer includes a plurality of anodes and a plurality of first conductive bridges spaced from each other, a plurality of first through holes is formed in the pixel defining layer corresponding to the first conductive bridges, each first electrode row includes a plurality of first sensing electrodes, and the first sensing electrodes are electrically connected to the first conductive bridges through the first through holes.

In the AMOLED display panel of one embodiment of the present disclosure, both of the anodes and the first conductive bridges are made of transparent indium tin metal oxide material.

In the AMOLED display panel of one embodiment of the present disclosure, the pixel defining layer includes a first pixel defining layer and a second pixel defining layer, the first pixel defining layer is formed on the anode layer, the second metal layer is formed on the first pixel defining layer, and the second pixel defining layer is formed on the second metal layer.

In the AMOLED display panel of one embodiment of the present disclosure, the second metal layer includes a plurality of second conductive bridges distributed in an array, a plurality of second through holes is formed in the second pixel defining layer corresponding to the second conductive bridges, and the cathodes are electrically connected to the second conductive bridges through the second through holes.

In the AMOLED display panel of one embodiment of the present disclosure, the second metal layer includes a plurality of second conductive bridges and a plurality of third conductive bridges insulated from each other, the first sensing electrodes formed in the first electrode rows are electrically connected to the third conductive bridges through the third through holes, and the cathodes are electrically connected to the second conductive bridges through the second through holes.

In the AMOLED display panel of one embodiment of the present disclosure, the second electrode rows each include a plurality of second sensing electrodes spaced from each other, and the second sensing electrodes are electrically connected to each other by connecting portions.

In the AMOLED display panel of one embodiment of the present disclosure, the second sensing electrodes and the connecting portions are formed by a one-piece structure.

In the AMOLED display panel of one embodiment of the present disclosure, the first sensing electrodes, the second sensing electrodes, the connecting portions and the cathodes are manufactured by a same mask process.

In the AMOLED display panel of one embodiment of the present disclosure, the sensing electrodes are electrodes for fingerprint recognition.

The present disclosure provides an AMOLED display panel, the AMOLED display panel includes: a base substrate; an anode layer formed on the base substrate; a pixel defining layer formed on the anode layer, and defining a pixel region; a light emitting layer formed on the anode layer corresponding to the pixel region; a second metal layer formed on the pixel defining layer; and a cathode layer formed on the pixel defining layer and the second metal layer; the cathode layer includes a plurality of cathodes corresponding to the light emitting layer and a plurality of sensing electrodes electrically insulated from the cathodes, and a plurality of first electrode rows and a plurality of second electrode rows are formed by the sensing electrodes and insulated from each other, the first electrode rows and the second electrode rows are arranged to cross each other.

In the AMOLED display panel of one embodiment of the present disclosure, the anode layer includes a plurality of anodes and a plurality of first conductive bridges spaced from each other, a plurality of first through holes is formed in the pixel defining layer corresponding to the first conductive bridges, each first electrode row includes a plurality of first sensing electrodes, and the first sensing electrodes are electrically connected to the first conductive bridges through the first through holes.

In the AMOLED display panel of one embodiment of the present disclosure, both of the anodes and the first conductive bridges are made of transparent indium tin metal oxide material.

In the AMOLED display panel of one embodiment of the present disclosure, the pixel defining layer includes a first pixel defining layer and a second pixel defining layer, the first pixel defining layer is formed on the anode layer, the second metal layer is formed on the first pixel defining layer, and the second pixel defining layer is formed on the second metal layer.

In the AMOLED display panel of one embodiment of the present disclosure, the second metal layer includes a plurality of second conductive bridges distributed in an array, a plurality of second through holes is formed in the second pixel defining layer corresponding to the second conductive bridges, and the cathodes are electrically connected to the second conductive bridges through the second through holes.

In the AMOLED display panel of one embodiment of the present disclosure, the second metal layer includes a plurality of second conductive bridges and a plurality of third conductive bridges insulated from each other, the first sensing electrodes formed in the first electrode rows are electrically connected to the third conductive bridges through the third through holes, and the cathodes are electrically connected to the second conductive bridges through the second through holes.

In the AMOLED display panel of one embodiment of the present disclosure, the second electrode rows each include a plurality of second sensing electrodes spaced from each other, and the second sensing electrodes are electrically connected to each other by connecting portions.

In the AMOLED display panel of one embodiment of the present disclosure, the second sensing electrodes and the connecting portions are formed by a one-piece structure.

In the AMOLED display panel of one embodiment of the present disclosure, the first sensing electrodes, the second sensing electrodes, the connecting portions and the cathodes are manufactured by a same mask process.

In the AMOLED display panel of one embodiment of the present disclosure, the sensing electrodes are electrodes for fingerprint recognition.

The beneficial effect of this invention is: comparing with an AMOLED display panel of the prior art, in the AMOLED display panel of the application, the cathodes and the sensing electrodes are formed in the cathode layer by a patterned process, adjacent second sensing electrodes defined in the second electrode rows are connected with each other by the cathode layer, adjacent first sensing electrodes defined in the first electrode rows are connected by the first conductive bridges, adjacent cathodes are connected with each other by the second conductive bridges. Capacitors are defined by the first sensing electrodes and the second sensing electrodes to achieve a function of fingerprint identification function. This design can effectively use the screen interior space to embed fingerprint identification models into the panel, to decrease a space placed by the fingerprint identification models and defined in an edge of the panel, to increase a ratio of the display area, to achieve full screen design and to set the fingerprint identification models in the front of the display panel to conform to using habits.

### BRIEF DESCRIPTION OF THE DRAWINGS

The accompanying figures to be used in the description of embodiments of the present disclosure or prior art will be described in brief to more clearly illustrate the technical solutions of the embodiments or the prior art. The accompanying figures described below are only part of the embodiments of the present disclosure, from which figures those skilled in the art can derive further figures without making any inventive efforts.

FIG. 1 is a schematic view of a fingerprint identification model of an AMOLED display panel in the prior art.

FIG. 2A is a schematic view of a film layer structure of an AMOLED display panel along a direction of a first electrode row of the AMOLED display panel of one exemplary embodiment according to the present disclosure.

FIG. 2B is a schematic view of a film layer structure of the AMOLED display panel along a direction of a second electrode row of the AMOLED display panel of one exemplary embodiment according to the present disclosure.

FIG. 3 is a schematic view of an underscreen fingerprint identification model of the AMOLED display panel of one exemplary embodiment according to the present disclosure.

FIG. 4 is a schematic view of a connecting relationship of film layers of the underscreen fingerprint identification model of the AMOLED display panel of one exemplary embodiment according to the present disclosure.

FIG. 5 is a schematic view of the AMOLED display panel of one exemplary embodiment according to the present disclosure.

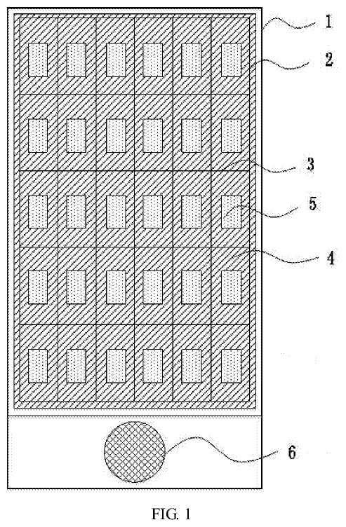

### DETAILED DESCRIPTION OF PREFERRED EMBODIMENTS

The description of following embodiment, with reference to the accompanying drawings, is used to exemplify specific embodiments which may be carried out in the present disclosure. Directional terms mentioned in the present disclosure, such as “top”, “bottom”, “front”, “back”, “left”, “right”, “inside”, “outside”, “side”, etc., are only used with reference to the orientation of the accompanying drawings. Therefore, the used directional terms are intended to illustrate, but not to limit, the present disclosure. In the drawings, the components having similar structures are denoted by same numerals.

The present disclosure is directed to a technology problem of a limited screen-to-body ratio caused by fingerprint identification units and the display area separated with each other of the prior art. The present disclosure can solve the above defects.

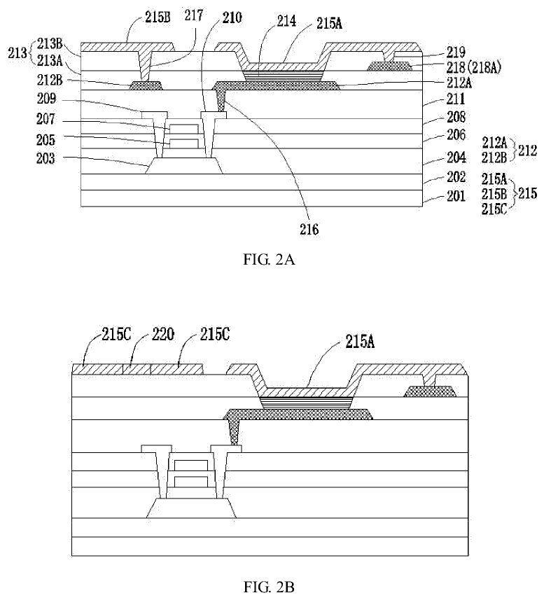

Referring to FIG. 2A, FIG. 2A is a schematic view of a film layer structure of an AMOLED display panel along a direction of a first electrode row of the AMOLED display panel of one exemplary embodiment according to the present disclosure. The AMOLED display panel includes: a base substrate 201; a buffer layer 202 formed on the base substrate 201; a thin film transistor layer formed on the buffer layer 202, wherein the thin film transistor layer includes an active layer 203, an insulating interlayer 204, a first gate electrode 205, a gate insulating layer 206, a second gate electrode 207, and insulating layer 208 formed in sequence and source electrodes 209 and drain electrodes 210 formed two ends of the active layer 203 and penetrating through the insulating interlayer 204, the gate insulating layer 206, and the insulating layer 208; a flatting layer 211 formed on the thin film transistor layer; an anode layer 212 formed on the flatting layer 211; a pixel defining layer 213 formed on the anode layer 212 and defining a pixel area, wherein the pixel defining layer 213 includes a first pixel defining layer 213A and a second pixel defining layer 213B formed in sequence; a light emitting layer 214 formed on the anode layer 212 and corresponding to the pixel area; a second metal layer 218 formed on the first pixel defining layer 213A; and a cathode layer 215 formed on the pixel defining layer 213.

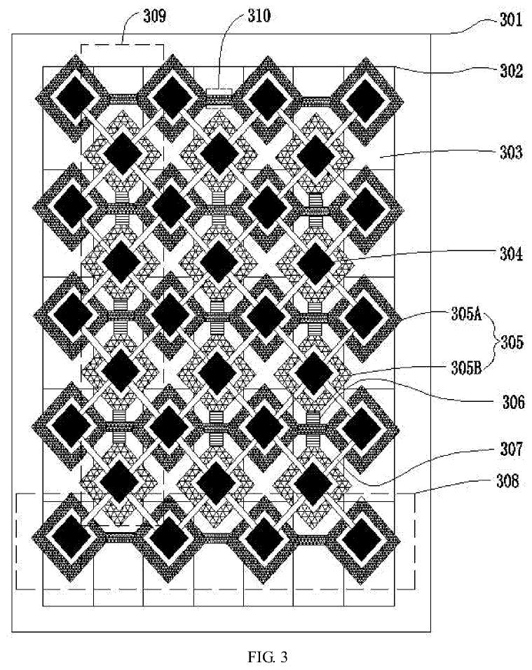

The cathode layer 215 includes a plurality of cathodes 215A formed on the light emitting layer 214 and a plurality of first sensing electrodes 215B and a plurality of second sensing electrodes 215C (referring to FIG. 2B) electrically insulated from the cathodes 215A. The first sensing electrodes 215B are arranged and define a plurality of first electrode rows (labeled as 309 in FIG. 3). The second sensing electrodes 215C are arranged and define a plurality of second electrode rows (labeled as 308 in FIG. 3).

The first sensing electrodes 215B corresponding to the non-pixel area of the pixel defining layer 213 are electrically insulated from the cathodes 215A formed in a same layer. The anode layer 212 includes a plurality of anodes 212A corresponding to the light emitting layer 214 and a plurality of first conductive bridges 212B electrically insulated from the anodes 212A. A plurality of first through holes 217 penetrates through the first pixel defining layer 213A and the second pixel defining layer 213B and corresponds to the first conductive bridges 212B. The first sensing electrodes 215B of the first electrode rows are electrically connected to the first conductive bridges 212B by the first through holes 217 to the first electrode rows being paralleled with each other. In one embodiment, both of the anodes 212A and the first conductive bridges 212B are made of transparent indium tin metal oxide material.

The second metal layer 218 includes a plurality of second conductive bridges 218A distributed in an array (label as 311 in FIG. 3). Each second conductive bridge 218A is placed between two adjacent cathodes 215A. A plurality of second through holes 219 is defined in second pixel defining layer 213B and corresponds to the second conductive bridges 218A. Two adjacent cathodes 215A are electrically connected to the second conductive bridge 218A by the second through holes 219 to make the cathodes 215A of an effective light emitting area to remain a same negative voltage. Material of the second conductive bridges 218A can be same as material of the anode 212A, or made of other conductive materials.

Referring to FIG. 2B, FIG. 2B is a schematic view of a film layer structure of the AMOLED display panel along a direction of a second electrode row of the AMOLED display panel of one exemplary embodiment according to the present disclosure. Comparing with the first electrode rows, the second sensing electrodes 215C of the second electrode rows (labeled as 308 of the FIG. 3) are connected by a plurality of connect portions 220. The second sensing electrodes 215C and the connecting portions 220 are formed by a one-piece structure. The second sensing electrodes 215C and the connecting portions 220 are formed by a same mask. In one embodiment, the cathodes 215A, the first sensing electrodes and the one-piece structures of the second sensing electrodes 215C and the connect portions 220 are formed by a same mask. Each connect portion 220 is connected between two adjacent second sensing electrodes 215C of one second electrode row to make the second electrode rows electrically insulated from each other.

Referring to FIG. 3, FIG. 3 is a schematic view of an underscreen fingerprint identification model of the AMOLED display panel of one exemplary embodiment according to the present disclosure. The AMOLED display panel includes: a base substrate 301; an effective light emitting area 302 defined in the base substrate 301 and including a plurality of pixel area 303, wherein each pixel area 303 includes a patterned cathode 304 and a plurality of sensing electrodes 305 formed in a same layer with the cathode 304 and separated from each other; the sensing electrodes 305 is arranged and defined as the first electrode rows 309 and the second electrode rows 308. The first electrode rows 309 and the second electrode rows 308 are arranged to cross and electrically insulated from each other. In this embodiment, each sensing electrode 305 is a roll around the cathode 304. Sizes and sharps of the sensing electrodes 305 are not limited.

The sensing electrodes 305 includes a plurality of first sensing electrodes 305B placed in the first electrode rows 309 and a plurality of second sensing electrodes 305A placed in the second electrode rows 308. Each connect portion 310 is connected between two adjacent second sensing electrodes 305A. The cathodes 304, the sensing electrodes 305 and the connect portions 310 are formed by a same mask. The connect portions 310 are connected between the second sensing electrodes 305A to make the second electrode rows 308 separated with each other. The first conductive bridges 306 are electrically insulated from the sensing electrodes 305. Each of the first conductive bridges 306 is formed between two adjacent first sensing electrodes 305B. The first conductive bridges 306 are connected between the first sensing electrodes 305B by the first through holes to make the first electrode rows 309 separated with each other. The first conductive bridges 306 are made from the anode layer.

Two adjacent cathodes 304 are electrically connected with each other by the second through holes and the second conductive bridge 307 of the pixel defining layer. In one embodiment, each cathode 304 corresponding to the first electrode row 309 is connected with a neighbor cathode 304 of the second electrode row 308. The second conductive bridges 307 can be formed in the anode layer or the second metal layer. The first electrode rows 309 and the second electrode rows 308 are arranged across and electrically separated from each other. In this embodiment, the sensing electrodes 305 are fingerprint identification electrodes. The first sensing electrodes 305B are used to be coupled with the second sensing electrodes 305A to form capacitors to achieve a function of fingerprint identification.

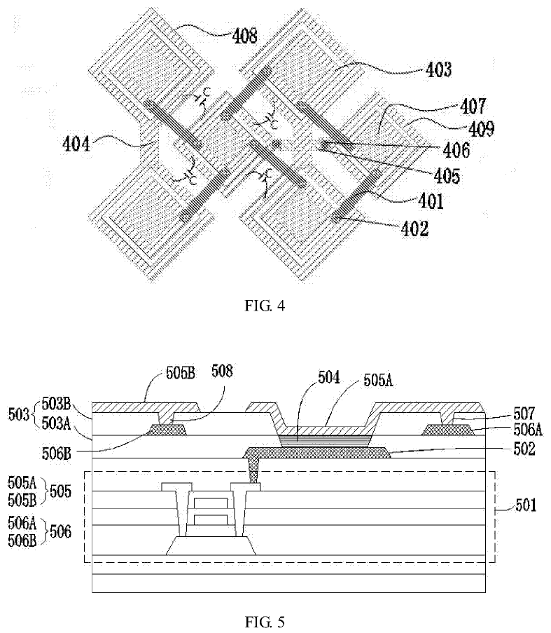

Referring to FIG. 4, FIG. 4 is a schematic view of a connecting relationship of film layers of the underscreen fingerprint identification model of the AMOLED display panel of one exemplary embodiment according to the present disclosure. The AMOLED display panel includes: a plurality of cathodes 403 facing the light emitting layer 407, wherein two adjacent cathodes 403 are connected to the second conductive bridge 401 by the second through holes 402; a plurality of first sensing electrodes 409 connected to the first conductive bridges 405 by the first through holes 406; a plurality of second sensing electrodes 408 connected to the connect portions 404 formed in a same layer. The first conductive bridges 405 and the second conductive bridges 401 are electrically insulated from each other. One first sensing electrode 409 is coupled with a neighbor second sensing electrode 408 to form a capacitor to achieve a function of fingerprint identification.

Referring to FIG. 5, FIG. 5 is a schematic view of the AMOLED display panel of one exemplary embodiment according to the present disclosure. Compared with the above embodiments, distinguishing techniques are: a plurality of anode 502 distributed in an array is formed on the thin film transistor layer 501 of the AMOLED display panel; a pixel defining layer 503 is formed on the anodes 502 and defines a plurality of pixel areas, the pixel defining layer 503 includes a first pixel defining layer 503A and the second pixel defining layer 503B formed in sequence; the second metal layer 506 is formed on a surface of the first pixel defining layer 503A. The second metal layer 506 includes a plurality of second conductive bridges 506A and a plurality of third conductive bridges 506B electrically insulated from the second conductive bridges 506A; the second pixel defining layer 503B has a plurality of third through holes 508 corresponding to the third conductive bridges 506B and a plurality of second through holes 507 corresponding to the second conductive bridges 506A; a light emitting layer 504 is formed on the pixel areas; a cathode layer 505 is formed on the light emitting layer 504, the cathode layer 505 includes a plurality of cathodes 505A and the first electrode rows (labeled as 309 in FIG. 3) and the second electrode rows (labeled as 308 in FIG. 3) electrically insulated from each other. Two adjacent first sensing electrodes 505B of the first electrode rows are connected with each other by the third through holes 508 and the third conductive bridges 506B. Two adjacent cathodes 505A are electrically connected to the second conductive bridge 506A by the second through holes 507.

Other structure of the AMOLED of this embodiment is same as the above embodiments, and won't go into details here.

Comparing with an AMOLED display panel of the prior art, in the AMOLED display panel of the application, the cathodes and the sensing electrodes are formed in the cathode layer by a patterned process, adjacent second sensing electrodes defined in the second electrode rows are connected with each other by the cathode layer, adjacent first sensing electrodes defined in the first electrode rows are connected by the first conductive bridges, adjacent cathodes are connected with each other by the second conductive bridges. Capacitors are defined by the first sensing electrodes and the second sensing electrodes to achieve a function of fingerprint identification function. This design can effectively use the screen interior space to embed fingerprint identification models into the panel, to decrease a space placed by the fingerprint identification models and defined in an edge of the panel, to increase a ratio of the display area, to achieve full screen design and to set the fingerprint identification models in the front of the display panel to conform to using habits.

As is understood by persons skilled in the art, the foregoing preferred embodiments of the present disclosure are illustrative rather than limiting of the present disclosure. It is intended that they cover various modifications and that similar arrangements be included in the spirit and scope of the present disclosure, the scope of which should be accorded the broadest interpretation so as to encompass all such modifications and similar structures.

What is claimed is:

1. An active matrix organic light emitting diode (AMOLED) display panel, comprising:
a base substrate;
an anode layer formed on the base substrate;
a pixel defining layer formed on the anode layer, and defining a pixel region;
a light emitting layer formed on the anode layer corresponding to the pixel region;
a second metal layer formed on the pixel defining layer;
a cathode layer formed on the pixel defining layer and the second metal layer;
wherein the cathode layer comprises a plurality of cathodes corresponding to the light emitting layer and a plurality of sensing electrodes electrically insulated from the cathodes, and a plurality of first electrode rows and a plurality of second electrode rows are formed by the sensing electrodes and insulated from each other.

2. The AMOLED display panel of claim 1, wherein the anode layer comprises a plurality of anodes and a plurality of first conductive bridges spaced from each other, a plurality of first through holes is formed in the pixel defining layer corresponding to the first conductive bridges, each first electrode row comprises a plurality of first sensing electrodes, and the first sensing electrodes are electrically connected to the first conductive bridges through the first through holes.

3. The AMOLED display panel of claim 2, wherein both of the anodes and the first conductive bridges are made of transparent indium tin metal oxide material.

4. The AMOLED display panel of claim 1, wherein the pixel defining layer comprises a first pixel defining layer and a second pixel defining layer, the first pixel defining layer is formed on the anode layer, the second metal layer is formed on the first pixel defining layer, and the second pixel defining layer is formed on the second metal layer.

5. The AMOLED display panel of claim 4, wherein the second metal layer comprises a plurality of second conductive bridges distributed in an array, a plurality of second through holes is formed in the second pixel defining layer corresponding to the second conductive bridges, and the cathodes are electrically connected to the second conductive bridges through the second through holes.

6. The AMOLED display panel of claim 4, wherein the second metal layer comprises a plurality of second conductive bridges and a plurality of third conductive bridges insulated from each other, the first sensing electrodes formed in the first electrode rows are electrically connected to the third conductive bridges through the third through holes, and the cathodes are electrically connected to the second conductive bridges through the second through holes.

7. The AMOLED display panel of claim 2, wherein the second electrode rows each comprise a plurality of second sensing electrodes spaced from each other, and the second sensing electrodes are electrically connected to each other by connecting portions.

8. The AMOLED display panel of claim 7, wherein the second sensing electrodes and the connecting portions are formed by a one-piece structure.

9. The AMOLED display panel of claim 7, wherein the first sensing electrodes, the second sensing electrodes, the connecting portions and the cathodes are manufactured by a same mask process.

10. The AMOLED display panel of claim 1, wherein the sensing electrodes are electrodes for fingerprint recognition.

11. An active matrix organic light emitting diode (AMOLED) display panel, comprising:
a base substrate;
an anode layer formed on the base substrate;
a pixel defining layer formed on the anode layer, and defining a pixel region;
a light emitting layer formed on the anode layer corresponding to the pixel region;
a second metal layer formed on the pixel defining layer;
a cathode layer formed on the pixel defining layer and the second metal layer;
wherein the cathode layer comprises a plurality of cathodes corresponding to the light emitting layer and a plurality of sensing electrodes electrically insulated from the cathodes, and a plurality of first electrode rows and a plurality of second electrode rows are formed by the sensing electrodes and insulated from each other, the first electrode rows and the second electrode rows are arranged to cross each other.

12. The AMOLED display panel of claim 11, wherein the anode layer comprises a plurality of anodes and a plurality of first conductive bridges spaced from each other, a plurality of first through holes is formed in the pixel defining layer corresponding to the first conductive bridges, each first electrode row comprises a plurality of first sensing electrodes, and the first sensing electrodes are electrically connected to the first conductive bridges through the first through holes.

13. The AMOLED display panel of claim 12, wherein both of the anodes and the first conductive bridges are made of transparent indium tin metal oxide material.

14. The AMOLED display panel of claim 11, wherein the pixel defining layer comprises a first pixel defining layer and a second pixel defining layer, the first pixel defining layer is formed on the anode layer, the second metal layer is formed on the first pixel defining layer, and the second pixel defining layer is formed on the second metal layer.

15. The AMOLED display panel of claim 14, wherein the second metal layer comprises a plurality of second conductive bridges distributed in an array, a plurality of second through holes is formed in the second pixel defining layer corresponding to the second conductive bridges, and the cathodes are electrically connected to the second conductive bridges through the second through holes.

16. The AMOLED display panel of claim 14, wherein the second metal layer comprises a plurality of second conductive bridges and a plurality of third conductive bridges insulated from each other, the first sensing electrodes formed in the first electrode rows are electrically connected to the third conductive bridges through the third through holes, and the cathodes are electrically connected to the second conductive bridges through the second through holes.

17. The AMOLED display panel of claim 12, wherein the second electrode rows each comprise a plurality of second sensing electrodes spaced from each other, and the second sensing electrodes are electrically connected to each other by connecting portions.

18. The AMOLED display panel of claim 17, wherein the second sensing electrodes and the connecting portions are formed by a one-piece structure.

19. The AMOLED display panel of claim 17, wherein the first sensing electrodes, the second sensing electrodes, the connecting portions and the cathodes are manufactured by a same mask process.

20. The AMOLED display panel of claim 11, wherein the sensing electrodes are electrodes for fingerprint recognition.
